(19) United States
(12) Patent Application Publication
(10) Pub. No.: US 2010/0275967 A1
(43) Pub. Date: Nov. 4, 2010

(54) Methods, facilities and simulations for a solar power plant

(76) Inventor: Ferdinand Seemann, Livermore, CA (US)

Correspondence Address: TUE NGUYEN, 496 OLIVE AVE, FREMONT, CA, 94539, US

(21) Appl. No.: 12/769,651

(22) Filed: Apr. 29, 2010

Related U.S. Application Data
(60) Provisional application No. 61/173,956, filed on Apr. 29, 2009.
(60) Provisional application No. 61/246,312, filed on Sep. 28, 2009.

(51) Int. Cl. H01L 31/042; H01L 31/18

(52) U.S. Cl. 136/244; 438/73; 257/E31.001

(57) ABSTRACT

In an embodiment, the present invention discloses a solar power plant, comprising gradually installing the solar panels to reach the desired power output after a plant construction time. The construction time is longer than an otherwise full time construction of solar power plant, typically 2 to 30 times longer, and typically ranging from 10 to 30 years. The construction time can be selected to achieve a desired capital spending or a power selling price. In addition, a solar panel plant can be constructed on or in a vicinity of the solar power plant to produce the required solar panels.

This application claims priority from U.S. provisional patent application Ser. No. 61/173,956, filed on Apr. 29, 2009, entitled “Methods and facilities for a solar power plant”; and from U.S. provisional patent application Ser. No. 61/246,312, filed on Sep. 28, 2009, entitled “Methods, simulations and facilities for a profitable solar power plant”; which are incorporated herein by reference.

### BACKGROUND

Solar power plants are gaining acceptance as a green source of energy, together with applications in remote areas where electricity or other utilities are not readily available. Typical solar power plants consist of a plurality of solar panels and inverters. The solar panels function as the electric power generators, and are connected in series or in parallel to achieve suitable voltage and current. The inverters are provided to feed the electrical grid via a joint mains transformer.

Solar panels are emergent technology, thus the generated electric power tends to be more expensive than the current existing oil, coal or nuclear based power plants. In addition, rapid developments of solar technology have provided successive generations of more-efficient solar cells, potentially rendering current solar technology to be obsolete in the next few years.

The commercial practicality of solar power plants has been critically limited by the adverse disparity between the value of the solar-generated electrical power versus the amortized aggregated cost of building the solar power plants, including the high cost and short life time of currently available solar panels. In a solar energy conversion system, the costs may be divided into three general areas. First, there is the necessary quantity of solar photovoltaic cells needed to provide the desired watt-hours of electrical energy per unit of time (usually the average minimum number of hours of sunshine per day). Secondly, there is the cost of electrical or mechanical parts in the system other than the solar cells, and the fabrication and installation costs. Finally, to be practical, the life expectancy of a solar energy system should generally be at least 20 years, and therefore, maintenance and repair costs must be considered as part of the initial design.

Typically, the time for return of the investment has exceeded the projected life of the solar panels, making their value more political than economic. For example, when all actual costs are accounted, the time to return the investment for a solar power generator system ranges from 30 years for a solar panel roof-cover to between 40 and 150 years for a state of the art two-axis tracking parabolic dish concentrator.

Thus, one important aspect of a solar power plant is its cost effectiveness: that is, the consideration of the total costs of acquisition, delivery, installation, maintenance, fuel, life expectancy, and the like—versus the market value of the utilities it would replace.

### SUMMARY OF THE DESCRIPTION

The present invention relates to methods, simulations and facilities for a solar power plant, such as the schematic construction, assembly, and transport of solar panels and the assembly of solar panels to the power plant; the arrangement of various sub-plant facilities to provide maintenance, repair and replacement of solar panels in the power plant. The present invention also relates to cost-effective solar power plants, addressing the infrastructure and the logistics of power generation from solar panels.

In an embodiment, the present invention discloses methods, and solar power plants constructed from the methods, for constructing a solar power plant, comprising gradually installing the solar panels to reach the desired power output after a plant construction time. The construction time is longer than an otherwise full time solar power plant build out, typically 2 to 30 times longer, and typically ranging from 10 to 30 years. In an embodiment, the build out time is selected to achieve a desired capital spending or a power selling price. Also, the gradual build out of the solar power plant can allow the installation of subsequent solar panels with improved solar technology, thus taking advantage of the rapid developments of solar technology. The gradual construction of the solar power plant can provide a gradual replacement of the solar panels after they reach their intended life time, spreading the capital required for renewing the solar power plant. The cost of new solar panels can be taken from the selling of electrical power, allowing the solar power plant to be sustained or grow with little or no additional infusion of external capital investment.

In an embodiment, the present invention discloses methods, and solar power plants constructed from the methods, for constructing a solar power plant, comprising constructing a solar panel plant in the solar power plant or in a vicinity of the solar power plant, and gradually installing the solar panels produced by the solar panel plant. The annual production rate of the solar panel plant is a fraction of the ultimate intended solar power plant output, which allows a small solar panel plant to gradually supply solar panels for a much larger solar power plant. For example, the yearly production rate of the solar panel plant is between 10 to 30 times smaller than the power output of the solar power plant, effectively requiring 10 to 30 years to fully populate the power plant with the solar panels produced from the solar panel plant. In an exemplary case, the solar power plant has a power output of 1 GW and the solar panel plant can have a yearly production rate of 25 to 100 MW, which would require between 10 to 40 years to generate enough solar panels for the fully built-out power plant.

In an embodiment, the solar panel plant manufactures photovoltaic (PV) cells connected together to form photovoltaic modules or panels. PVs include arrays of cells containing material that converts solar radiation into another form of energy, typically electricity. These photovoltaic panels are assembled in a solar photovoltaic (PV) power plant.

In an embodiment, the solar panel plant can produce solar cells, solar panels, and/or solar plant accessories, such as wiring and inverters. A solar panel includes anything that takes sunlight energy and converts it to another form of energy such as electricity or thermal energy. Panels may also include tubes, flat cells, rough surfaces, textured surfaces or any other form of solar energy converter. With an in-house solar panel plant, the cost for the solar panels supplied to the solar power plant can be much less than externally purchased solar panels. The solar panel plant can produce the complete solar generator system, including solar cell fabrication, solar panel assembly with wirings and harness, and solar plant accessories such as the balance of system, including mounting, wiring, electrical systems, inverters, substation with transformer. Alternatively, the solar panel plant can purchase the solar cells to assemble solar panels, together with solar plant accessories. The solar panel plant can also purchase the solar panels, and perform assembly with the solar plant accessories to be installed in the solar power plant.

In an embodiment, the solar panel plant can be constructed at a full time construction rate, or can be constructed in stages, with each stage producing solar panels at a portion of the solar panel plant output. For example, if the solar panel plant has a production rate of 100 MW/year, a 100 MW/year plant can be built to produce 100 MW solar panel output per year. Alternatively, the solar panel plant can be built in 4 stages, with each stage producing 25 MW/year output. The gradual building of the solar panel plant allows the capital spending to be spread out and further reduces external capital investment, since the revenue from the generated power can be used to construct later stages of the solar panel plant.

In an embodiment, the solar panel plant is specially optimized to produce specific solar panels for the solar power plant. There can be minimum variations in designs or features, which can contribute to reduced construction costs. In addition, with the special purpose solar panel plant, long term arrangements with raw material suppliers or other vendors can be considered to optimize material costs.

In an embodiment, the solar panel plant provides long term growth for the solar power plant with minimum expenses. New solar panels and systems can be produced at-cost, allowing the expansion of the solar power plant or the replacement of failing solar panels and system with minimum spending. In addition, the expenses are spread over a number of years, allowing them to be offset by the revenue from the generated power. Thus the solar power plant can be sustained or grow indefinitely without any new infusion of external capital investment.

In an embodiment, the present invention discloses a solar power plant comprising a gradual installing of solar panels, and with or without a solar panel plant. The present solar power plant can be optimized to be competitive with existing power plants employing traditional power generation technologies, in addition to providing greener energy.

In an embodiment, the present invention discloses methods and simulations for constructing a solar power plant meeting a criterion of either a desired power selling price or a target level of capital investment. The present methods can provide design considerations for a solar power plant that is affordable and cost effective. For example, the present methods focus on a desired power selling price, to ensure the solar power plant provides competitive power as compared to existing oil, coal, gas or nuclear based power plants. Alternatively, the present methods can focus on a desired maximum capital investment for building a solar power plant. The construction plan and the solar technology are selected to achieve this price or investment target.

### BRIEF DESCRIPTION OF THE DRAWINGS

FIGS. 1A-1C illustrate a prior art construction plan for a prior art power plant.

FIG. 2 illustrates an exemplary flowchart of a solar power plant according to embodiments of the present invention.

FIG. 3 illustrates an exemplary detailed flowchart of a solar power plant according to embodiments of the present invention.

FIGS. 4A-4C illustrate exemplary schematic behaviors of a solar power plant according to an embodiment of the present invention.

FIG. 5 illustrates different construction times for the solar power plant according to embodiments of the present invention.

FIGS. 6A-6B illustrate relationships between the construction time and the power selling price or the capital investment at break even points.

FIG. 7 illustrates the potential benefits of the present solar power plant according to embodiments of the present invention.

FIG. 8 illustrates a schematic behavior of profit curves with improvements in solar technology.

FIGS. 9A-9B illustrate an improvement on the relationship between the construction time and the power selling price or the capital investment at break even points.

FIG. 10A illustrates a same level of solar panel construction for the solar power plant during a desired period of operation of the solar power plant.

FIG. 10B illustrates a perpetual solar power plant without any additional capital expenditure or investment.

FIG. 11 illustrates an exemplary flowchart of a solar power plant comprising a solar panel plant according to embodiments of the present invention.

FIG. 12 illustrates an exemplary detailed flowchart of a solar power plant comprising a solar panel plant according to embodiments of the present invention.

FIGS. 13A-13F illustrate an exemplary sequence of solar panel installation according to embodiments of the present invention.

FIG. 14 illustrates a comparison between solar power plant with and without a solar panel plant.

FIGS. 15A-15D illustrate a schematic construction of a solar panel plant in stages according to embodiments of the present invention.

FIG. 16 illustrates an exemplary flowchart of a solar power plant according to embodiments of the present invention.

FIG. 17 illustrates an exemplary flowchart of a solar power plant according to embodiments of the present invention.

### DETAILED DESCRIPTION OF THE PREFERRED EMBODIMENTS

The present invention is directed to emergent technologies, such as utilizing emergent technologies in a cost effective manner. The emergent technologies are better than existing technologies, with improvements and innovations forecasted in the very near future. The emergent technologies thus tend to be costly, and command a premium price. In addition, current emergent technologies can become obsolete, or superseded by better processes within a few years, making investments in emergent technologies risky. In the following description, the present invention is described in terms of solar energy, but can be applied to other emergent technologies, such as wind turbine.

Solar power plants are slowly gaining acceptance as an alternative source of power generation. However, the cost of the generated electricity from a solar plant still does not match with that of a comparably sized existing power plant, such as a fossil fuel-based power plant. In an embodiment, the present invention discloses cost-effective solar power plants, addressing the infrastructure and the logistics of power generation from solar panels to make solar power affordable and profitable. The present invention also discloses methods, simulations and facilities for a solar power plant, such as the arrangement of various sub-plant facilities, the construction, assembly, and transport of solar panels and the assembly of solar panels to the power plant, the maintenance, repair and replacement of solar panels in the power plant. The present invention can offer solar power plants that can provide power prices competitive with existing mature technologies despite the usage of costly and rapidly evolving emergent solar technology.

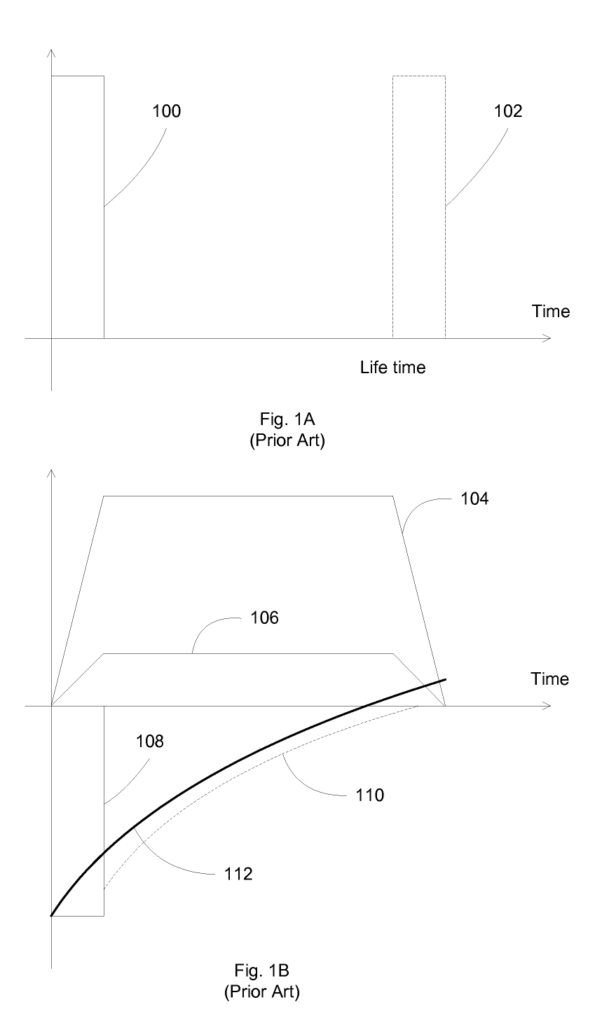

FIGS. 1A-1C illustrate a prior art construction plan, for example, a prior art power plant. The construction 100 of the power plants proceeds at a full time construction plan, typically as fast as possible, limited only by the availability of materials and labor. For a typical plant, the construction time is about six months to one year. For present day solar power plants, the construction time can be longer, due to the slow ramp up output of solar panel plants. After the life time of the equipment, e.g., the solar panels, the construction 102 re-starts to replace the failed solar panels with new ones.

FIG. 1B illustrates various characteristics of a prior art solar power plant, for example, as described in FIG. 1A. This figure describes typical behaviors of a power plant within the life time of the solar panels, for example, with the construction 100 of solar panel. For new construction 102, the behaviors are repeated in time.

The power output 104 of the power plant stabilizes at the maximum power output for the life time of the solar panels, with the ramp up time and the ramp down time related to the time of construction 100. With the prior art plan of construction, the construction cost 108 occurs up front, and represents a significant portion of the capital investment for the construction and operation of the power plant. With the high up-front cost 108, the financing amount 110 can also be high, representing another large portion of the capital investment. After the construction time, the generated power can bring revenues 106 to the power plant, after subtracting operation and material costs. The net profit 112 depends on the power selling price, and can be significantly delayed, partially due to the payments of capital investment 108 and the financing 110.

FIG. 1C illustrates a relationship 114 between the profit of the prior art power plant as a function of the power selling price. Higher power selling prices bring higher profit, with a minimum break even value 116. Break even point 116 must be competitive with power prices from existing and matured technologies, such as oil and coal. In practice, this is difficult to achieve as emergent technologies tend to be costly, and typically require a premium price to reach break even. Thus, prior art power plants normally require subsidization to operate at a profit.

In an embodiment, the present invention discloses a novel solar power plant concept that can compete with existing matured technologies, using emergent and rapidly changing solar technology. The present concept stretches the construction of the solar power plant over a longer period of time, longer than an otherwise full time construction of solar power plant. In an embodiment, the stretched construction time is 2× to 30× longer. In another embodiment, the stretched construction time is between 10 to 30 years, as compared to a typical full time construction of many months or a few years. The long construction time allows the leverage of the rapidly improved solar technology, the self-feeding of the solar power plant construction, and the minimum capital investment to offer competitive power price with significantly improved return of investment.

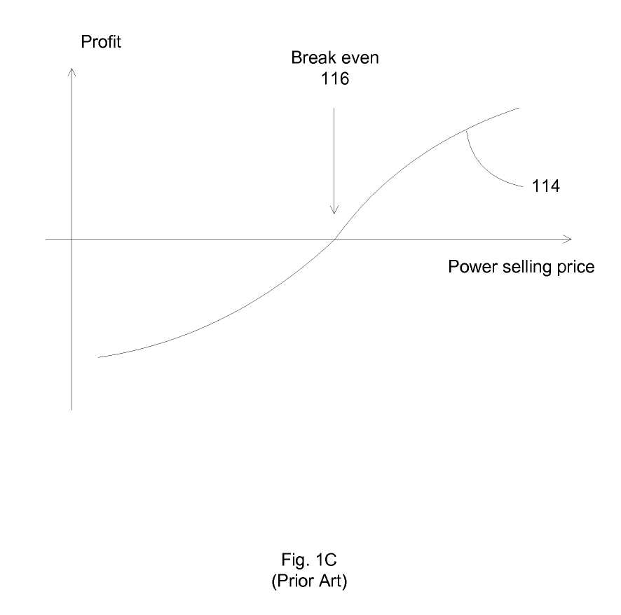

FIG. 2 illustrates an exemplary flowchart of a solar power plant according to embodiments of the present invention. Operation 1200 secures land for a power plant. The land can be continuous or can be separated by a reasonable distance for ease of transportation. The land is preferably located in an area with high level of insolation for optimum solar power production. The land can be located in less or non-populated areas for improved construction cost optimization. In an embodiment, the land can be subsidized, for example, by the local government to encourage green energy production. Operation 1202 gradually installs solar panels to reach the solar power plant output after a construction time longer than an otherwise full time construction of the solar power plant. The gradual installation can be continuous, in stages, or in steps with a waiting period between steps. The construction time can be determined by a simulation with a desired criterion such as a power selling price or a capital investment, together with other considerations. If the result is not satisfactory, e.g., the construction time is longer than practical, the simulation can adjust, changing power plant variables and inputs to reach an acceptable plant build out schedule. In general, the simulation focuses on the desired criterion, and not on the short term benefits. For example, high efficiency solar technology is desirable, but if it does not offer the long term cost reductions for the solar power plant, it will not be implemented. Considerations for long term cost reduction include long life time and proven reliability and solar technology with proven high efficiency may be considered high risk with high probability of failure before reaching the life time specification. In general, solar technology with proven 20-30 year reliability is considered to provide the required maturity in the selection of long term cost reductions for the present solar power plants.

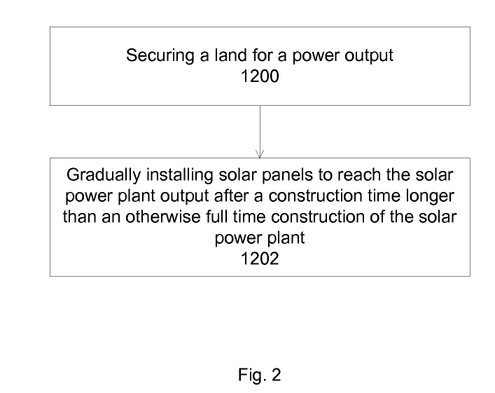

FIG. 3 illustrates an exemplary detailed flowchart of a solar power plant according to embodiments of the present invention. Operation 1300 secures land for a power plant. Operation 1302 gradually installs solar panels to reach the solar power plant output after a construction time longer than an otherwise full time construction of the solar power plant. The construction time can be more than 2×, between 2× and 30×, or even higher than the normal full time construction of a comparable solar power plant. The construction time can be more than 10 years, between 10 and 30 years, more than 30 years, more than half the life time of the solar panels, or about the life time of the solar panels. The construction time can be selected to achieve a desired capital expenditure, or a desired power selling price. In addition, the construction of the solar power plant can be continuous or intermittent, e.g., in stages. In an embodiment, the present solar power plant trades construction time for a desired power selling price or a desired capital investment.

A solar panel is defined as an object that can take sunlight energy and convert it into another form of energy, such as electricity or thermal energy. Panels also include tubes, flat cells, rough surfaces, and textured surfaces. Other types of solar energy converters may also be included in the use of “solar panel”.

The installed solar panels are selected to provide the best long term cost reduction for the solar power plant, such as those based on solar technology having proven long term reliability, proven test results, or meeting a desired power selling price. For example, low cost solar panels with unproven long term reliability are not considered, since the short term gain in the low cost purchase might not offset the long term loss due to premature failure. Since solar technology is rapidly improving, operation 1304 installs subsequent solar panels with improved solar technology as compared to previous solar panels. With the rapid advancements, new generations of solar panels can be introduced every few years, and therefore, with a long construction time, e.g., 10 to 30 years, many generations of improved solar panels can be installed in the present solar power plant. The gradual improvements of solar panels can bring additional benefits to the solar power plant, exploiting the rapid developments of solar technology together with the deployment of current solar technology. With the long term construction plan, the solar power plant can be perpetual, with old solar panels replaced by new improved solar panels, for example, after reaching their life time (operation 1306).

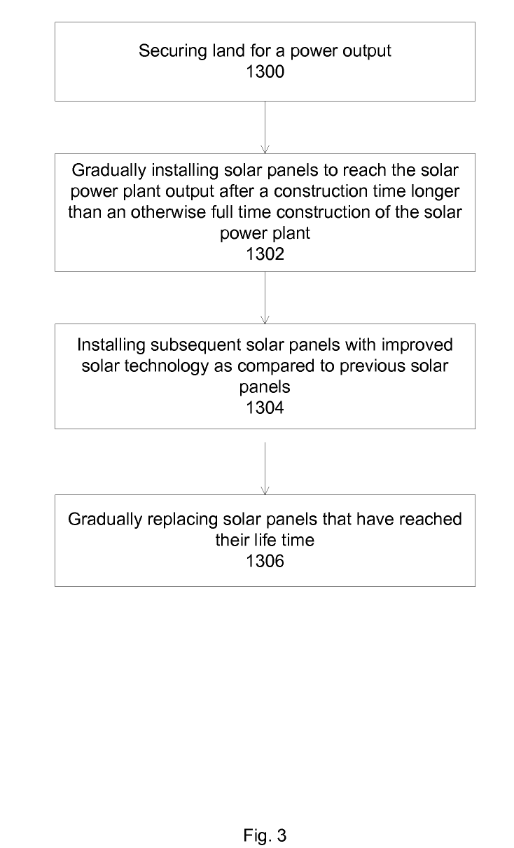

FIGS. 4A-4C illustrate exemplary schematic behaviors of a solar power plant according to an embodiment of the present invention. FIG. 4A illustrates a plant construction 200 where the solar panels are gradually installed during a construction time longer than a typical full time construction plan. Compared to a typical full time construction plan 100 shown in FIG. 1A, the present construction plan 200 is longer, and is designed to meet a desired criterion, such as power selling price competitive with existing power plants or a low capital expenditure. After the life time of the solar panels, the construction 202 of the solar panels is repeated, replacing the expired solar panels with new solar panels.

FIG. 4B illustrates various characteristics of the present exemplary solar power plant, for example, the solar power plant with the construction time 200 as described in FIG. 4A. This figure describes typical behaviors of a power plant within the life time of the solar panels, for example, with the construction 200 of solar panel. For new construction 202, the behaviors are repeated in time.

The power output 204 of the solar power plant stabilizes at the maximum power output for the life time of the solar panels, with the ramp up time and the ramp down time related to the time of construction 200. The construction cost 208 is spread over the construction time, and thus represents a much lower capital investment, resulting in significant reduction in the financing amount 210. After the construction time, the generated power can bring revenues 206 to the solar power plant. The net profit 212 depends on the power selling price, and can be adjusted based on the power selling price.

FIG. 4C illustrates a relationship 214 between the profits of the exemplary solar power plant as a function of the power selling price, with a break even value 216. Also shown in this figure is the profit curve 114 from the prior art power plant (FIG. 1C). In general, with the low capital spending 208 and low financing amount 210, the breakeven point 216 for the present solar power plant can be at a lower power selling price as compared to the prior art break even point 116. Thus the present solar power plant can offer power at a lower price than the prior art power plant, and still be profitable.

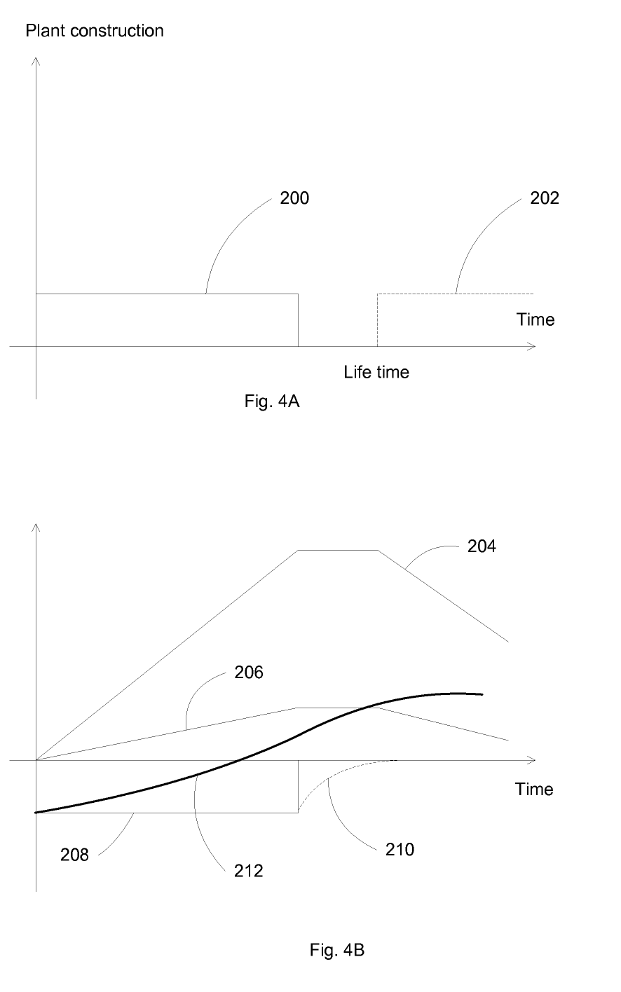

FIG. 5 illustrates different construction times 300 for the solar power plant according to embodiments of the present invention. The construction time 300 can be longer than the typical full time construction time, and can even longer than the life time of the solar panels. For a fixed life time of the solar panels, a construction time longer than the life time would result in lower power output, since the rate of failed solar panels due to reaching end of life time is greater than the installed solar panels. The life time of the solar panels can vary, since the earlier solar panels can have a shorter life time than the later solar panels which incorporate improved solar technology. Thus, in an embodiment, the present solar power plant considers the potential improvements in solar technology with respect to solar panel life time, and estimates a maximum construction time that can be longer than the life time of the first installed solar panels.

After the construction of the solar power plant, new solar panels can be installed to replace the failed solar panels. The installation rate of the new solar panels can be the same as the failure rate, thus keeping a constant power output. The installation rate of the new solar panels can be higher than the failure rate, thus expanding the power output of the solar power plant, for example, to adjacent land or at other locations. The installation rate of the new solar panels can be lower than the failure rate, thus reducing the power output, for example, to gradually phase out the solar power plant.

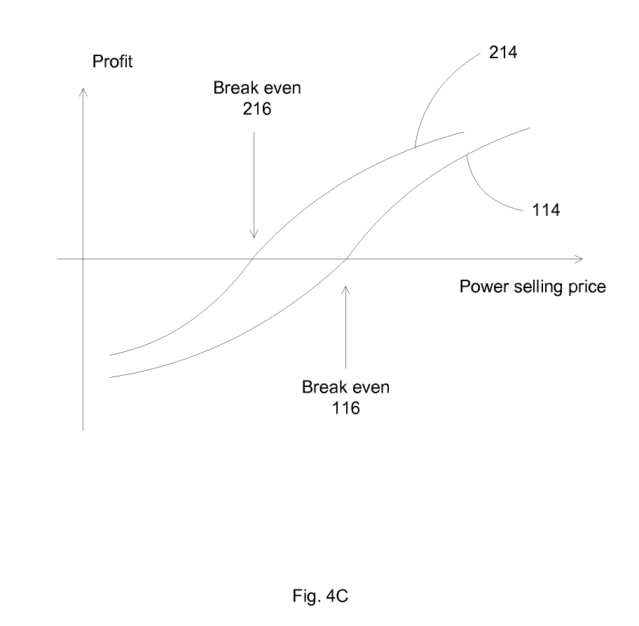

FIG. 6A illustrates a relationship 410 between the construction time and the power selling price at break even points. The curve 410 shows a schematic behavior and intend to represent the behavior without much detailed accuracy. At short construction time, the power selling price is high to achieve break even, for example, at the full time construction time. At longer construction times, the construction costs are lower, resulting in lower power selling price at breakeven point. From this relationship, a simulation for solar power plants can be performed, with the construction time calculated based on a desired power selling price.

FIG. 6B illustrates a relationship 420 between the construction time and the capital expense or investment at breakeven points. The curve 420 shows a schematic behavior and intend to represent the behavior without much detailed accuracy. At short construction time, the capital requirement is high to achieve break even, for example, at the full time construction time. At longer construction times, the construction costs are lower, resulting in lower capital requirement. From this relationship, a simulation for solar power plants can be performed, with the construction time calculated based on a desired capital expense.

In an embodiment, the gradual construction of solar panels over a long period of construction allows the implementation of potential improvements in solar technology. Solar technology has been advancing at a significant pace in the last few years, and additional significant improvements are foreseen within the next few years. Thus a prior art full time construction of solar power plant could be obsolete in the next few years, or at least, better solar panels, e.g., higher efficiency, lower fabrication cost and longer life time, can be expected to be available in the near future. However, solar energy is needed now, even at the current state of solar technology. Further, the implementation of current solar technology encourages the rapid developments of solar technology, enabling the potential solar panel improvements. Thus in an embodiment, the present gradual construction of solar power plant can provide solar power with currently available solar technology while leaving room for implementation of future improved solar technology when available.

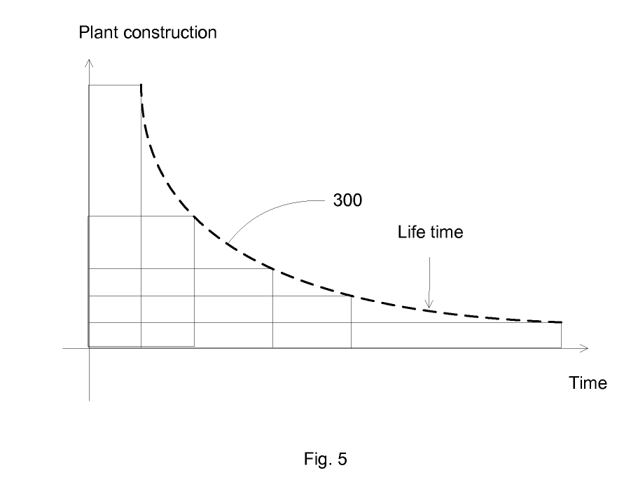

FIG. 7 illustrates the potential benefits of the present solar power plant according to embodiments of the present invention, comprising implementing improved solar panels during the construction time of the solar power plant. Improvements in solar technology can allow solar panel fabrication at a lower price, resulting in a reduction 510 of solar panel prices 508 to 518. In addition, consumable and operating costs can be reduced, together with increases in solar panel efficiency, resulting in an increase 520 in revenue 506 to 516. Further, life time of the newly installed solar panels can be increased, resulting in an increase 530 due to longer operating time and higher revenue.

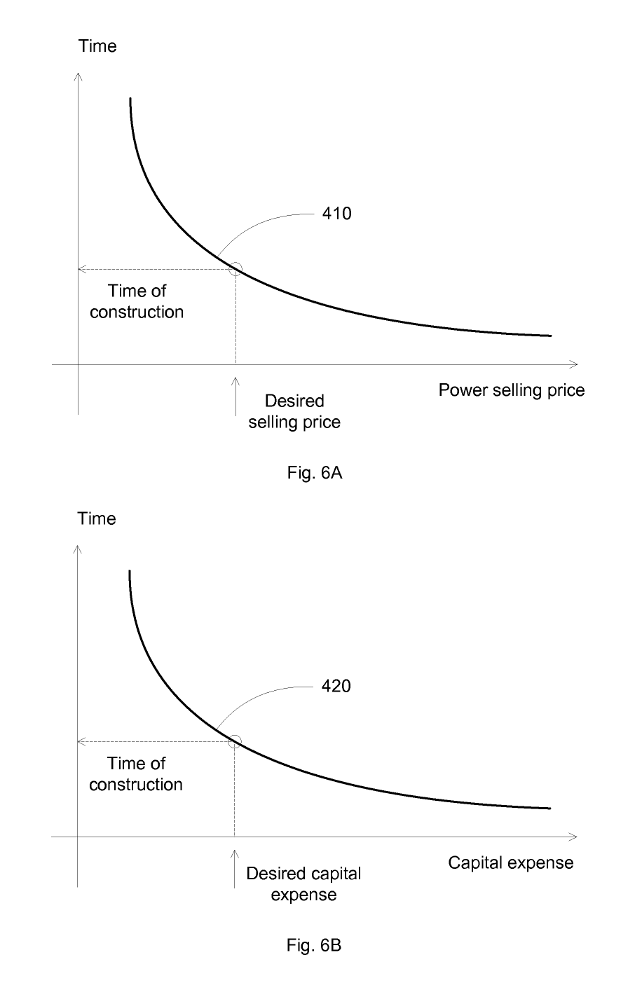

These advantages of implementing improved solar panels result in higher profit, or a shifting 620 in the profit curve from 604 to 614 toward a lower breakeven power selling price (see FIG. 8). Thus the gradual construction time with later improved solar panels can provide lower power selling price for the solar power plant.

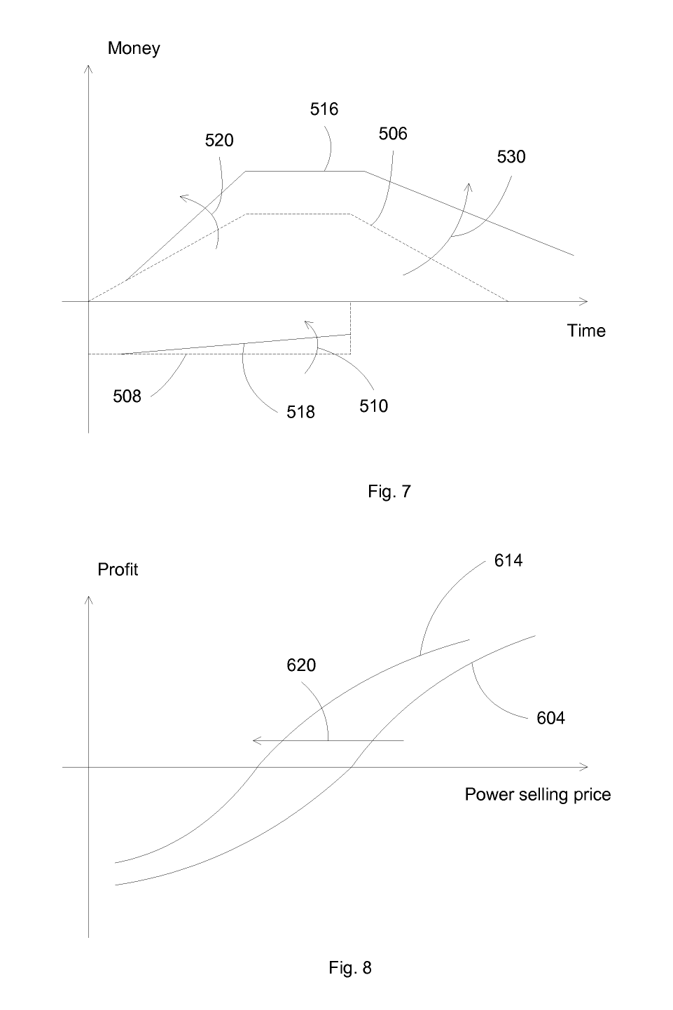

FIG. 9A illustrates an improvement on the relationship between the construction time and the power selling price at breakeven points. The improvement 715 shifts toward lower power selling price or shorter construction time with the implementation of improved solar panels during the later phase of the construction time. For the same construction time, the power selling price can be lower 710 with the implementation of new solar technology. For a same power selling price, the construction can be shorter 713.

FIG. 9B illustrates an improvement on the construction time and the capital expense or investment at breakeven points. The improvement 725 shifts toward lower capital expense or shorter construction time with the implementation of improved solar panels during the later phase of the construction time. For a same construction time, the capital expense can be lower 720 with the implementation of the new solar technology. For a same capital expense, the construction can be shorter 723.

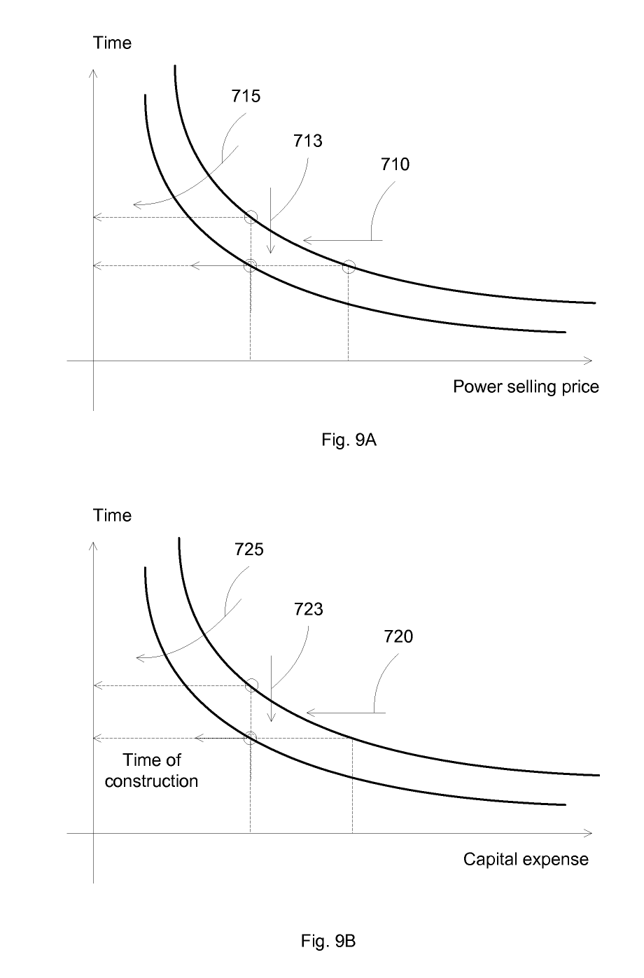

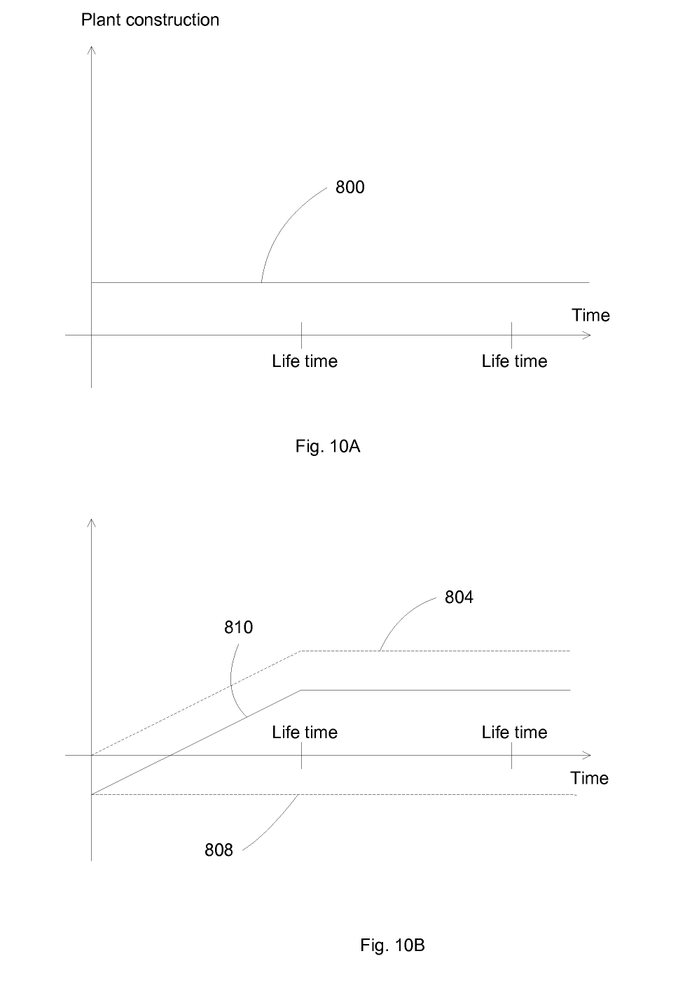

The present solar power plant can be sustained or grow indefinitely with a same or higher level of construction, respectively. FIG. 10A illustrates a same level of solar panel construction 800 for the solar power plant during a desired period of operation of the solar power plant. The construction time is continuous, representing installing new solar panels at the first life time period, and representing replacing previously installed solar panels with new ones (for example, due to life time failure) for subsequent life time periods. FIG. 10B illustrates a perpetual solar power plant without any additional external capital expenditure or investment. Curve 804 represents the revenue obtained from the generated power, and curve 808 represents the costs of solar panel purchase and installation. After a first life time period, the profit stabilizes, and the power plant is sustained indefinitely with a steady level of income. Growing or phasing out behaviors are similar, and the present solar power plant can also provide indefinite growth with the cost of growing supported by the revenue from the generated power, and without any additional external capital investment.

In an embodiment, the present invention discloses a solar photovoltaic (PV) power plant assembled from solar photovoltaic (PV) panels or modules manufactured within the vicinity of the PV power plant site. PV panels or modules are constructed of materials that are capable of converting solar energy, or sunlight, into another form of energy, typically electricity.

In an embodiment, the present invention discloses solar power plants and methods for constructing solar power plants comprising a solar panel plant constructed on or close to the solar power plant, for example, to lower power selling price and capital spending. With the manufacturing of solar panels on or in the vicinity of the power plant, significant cost reduction can be realized, such as reduced overhead, elimination of marketing, sales and distribution costs, and reduced margin in the panel manufacturing operation. In addition, other cost reductions can be achieved, such as minimizing packaging and shipping, and minimized cycle time.

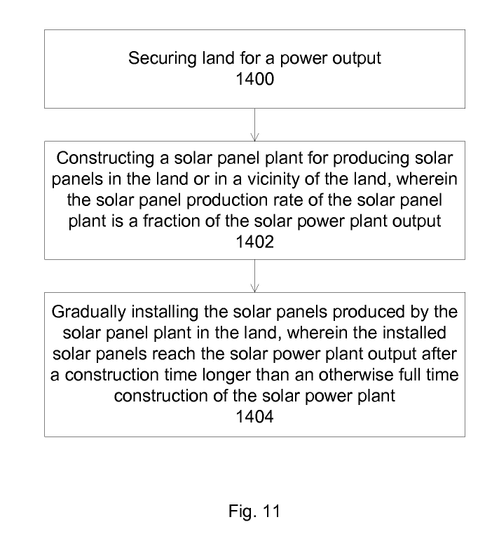

FIG. 11 illustrates an exemplary flowchart of a solar power plant comprising a solar panel plant according to embodiments of the present invention. Operation 1400 secures land for a power output plant. Operation 1402 constructs a solar panel plant for producing solar panels in the land or in the vicinity of the land, wherein the solar panel production rate of the solar panel plant is a fraction of the solar power plant output. Operation 1404 gradually installs solar panels to reach the solar power plant output after a construction time longer than an otherwise full time construction of the solar power plant.

In an embodiment, the present solar power plan comprises choosing a land area for the solar plant, constructing infrastructure on or near the power plant site where the solar panels are manufactured and assembled. The completed solar panels are then transported locally, for example, by delivering trucks, to the installation site to be installed. Power can be harvested immediately after the installation of each complete section of solar panels. A portion of the generated power can be channeled back to the panel manufacturing plan, further reducing factory expenses. Significant savings in transportation cost can be achieved, since only local transportation is required. Further, if the solar panel manufacturing site is strategically chosen, even local transportation can be optimized. Reduction in maintenance and repair cost can also be achieved, since solar panel expertise is located in the local area.

In an embodiment, the present solar power plant comprises a manufacturing facility which can comprise at least a panel assembly plant, serving to assemble the solar components into complete panels. The panel assembly can comprise the final assembly steps, such as electrical and mechanical cable harnesses and support. The panel assembly plant typically requires basic assembly skills with basic raw materials such as cables and frames, thus these skills and materials can be provided by local workers and materials. The integrated panel assembly plant can provide saving to the power plant, together with the utilization of local resources.

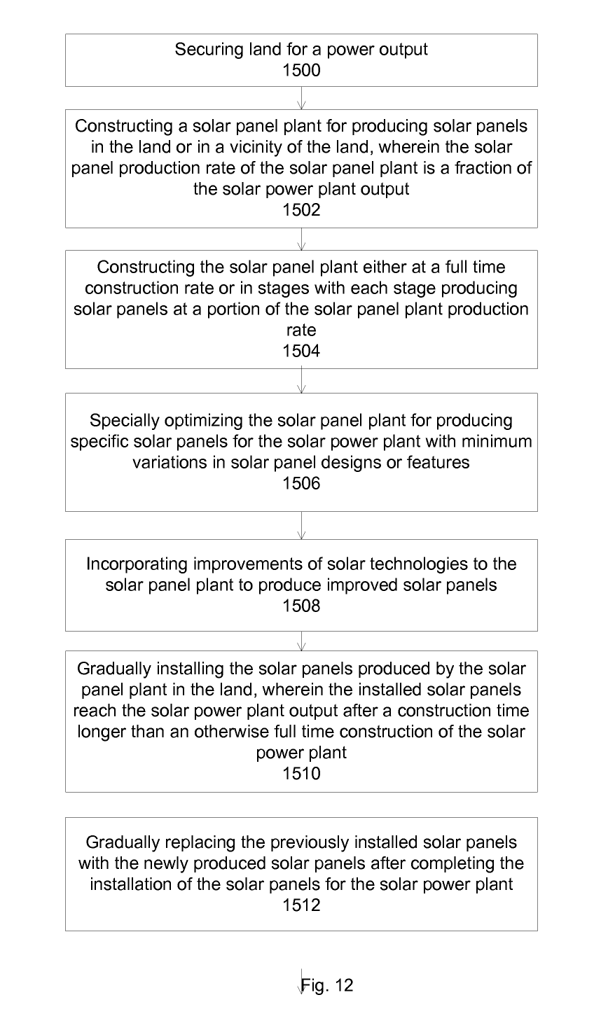

FIG. 12 illustrates an exemplary detailed flowchart of a solar power plant comprising a solar panel plant according to embodiments of the present invention. Operation 1500 secures land for a power output plant. Operation 1502 constructs a solar panel plant for producing solar panels in the land or in a vicinity of the land, wherein the solar panel production rate of the solar panel plant is a fraction of the solar power plant output, which allows a small solar panel plant to gradually supply solar panels for a much larger solar power plant. For example, the yearly production rate of the solar panel plant is between 2 to 50 times smaller than the power output of the solar power plant, effectively requiring 2 to 50 years to fully populate the power plant with the solar panels produced from the solar panel plant. In an exemplary case, the solar power plant has a power output of 10 GW and the solar panel plant can have a yearly production rate of 200 MW to 2 GW, which would require between 5 to 50 years to generate enough solar panels for the power plant.

In an embodiment, the manufacturing capability of the local solar panel facility is designed to support a portion of the power plant, for example, a yearly output of the solar panel facility can supply an area section of the power plant. In an aspect, the capacity of the fabrication facility is inversely related to the lifetime of the solar panel. In an aspect, the capacity of the fabrication facility is higher, with the excess panels sold or stored. The capacity can be lower, with the required panels purchased from outside services.

For example, if the lifetime of the solar panel is 30 years, the yearly output of the panel fabrication facility can be about 1/30 of the power plant capacity. After finishing installation of the 30th year output, the fabrication facility is ready to replace the first year installation. Thus the fabrication facility is always needed, with the panel outputs always ready to be installed at the power plant. In an aspect, the fabrication facility then becomes a permanent portion of the power plant, supplying replacement panels after the expiration of their life time. The small and optimized size of the panel fabrication facility can minimize the upfront construction cost. The gradual installation of solar panels can address the growth demand of power, matching the low capital investment with the gradual power increase. In addition, a manufacturing facility can be designed to supply panels to multiple nearby power plants. In an embodiment, the yearly output can be higher or lower than the inverse of the lifetime. The 30 year value serves as an example, and the lifetime of a panel can be 5, 10, 20, 30, or anywhere in between.

Operation 1504 constructs the solar panel plant either at a full time construction rate, a gradual construction rate or in stages with each stage producing solar panels at a portion of the solar panel plant production rate. At full time construction rate, the solar panel plant is built as fast as possible, limited only by the availability of equipment and labor. The capital spending is high, but the production is fast, and solar panels can be produced at the solar panel plant capacity. Alternatively, the solar panel plant can be constructed gradually, such as continuously or in stages over a longer period of time, with or without a resting period in between. Similar to the installation of the solar panels on the solar power plant, the gradual construction of the solar panel plant can reduce the need for external capital investment or borrowing, since the produced solar panels can generate revenue to support subsequent stages of the solar panel plant construction.

In an embodiment, the solar panel plant can produce complete solar panel systems ready to be installed, including solar cell fabrication, solar panel assembly with wiring and harness, and balance of system comprising mounting, wiring, electrical systems, inverters, substation with transformer. Alternatively, the solar panel plant can buy solar cells for assembling solar panels and balance of system. Also, the solar panel plant can buy solar panels and produce or assemble the balance of system.

In an embodiment, the present solar power plant comprises a manufacturing facility which comprises at least a solar cell fabrication plant, serving to produce solar cell substrates. The solar fabrication plant can produce solar cells from single crystal, multicrystalline or thin film semiconductor substrates. The solar fabrication plant can also produce thin film solar cell on substrates such as glass, polymer or metal. The fabrication plant can use consumables such as chemicals, gases, vapor, metal sputter target, and metal pastes, and substrates such as wafers or glass, which can be delivered to the plant. The fabrication plant can acquire the equipment from a turnkey solar panel manufacturer, together with training plan for operation. Thus local resources can also be utilized.

In an embodiment, the present solar power plant comprises a manufacturing facility which comprises at least a solar panel assembling plant, serving to assemble solar cell substrates onto solar panels. The solar fabrication plant can produce, purchase or assemble wiring and harness to connect solar cells to form solar panels ready to be installed.

In an embodiment, the present solar power plant comprises a manufacturing facility which comprises production or assembling support components, such as balance of system, for the solar power plant. For example, the support component can include a battery fabrication plant, serving to produce battery storage for the installed solar panels. Other components can also be produced or assembled at the solar panel plant.

Operation 1506 optimizes the solar panel plant for producing specific solar panels for the solar power plant with minimum variations in solar panel designs or features. The solar panel plant has a captured market with minimum variations, meaning to produce only a few types of solar panels for the in-house solar power plant. Thus the construction and operating costs of the solar panel plant can be greatly reduced. In addition, with minimum design variations and projected production rate, the solar panel plant can form long term agreements with supply vendors, such as material or labor, to achieve even better cost reduction.

Operation 1508 incorporates improvements of solar technologies to the solar panel plant to produce improved solar panels. Solar technology is rapidly changing, and thus, in an embodiment, the solar panel plant performs continuous updating of equipment and facility to keep up with the best in solar panel technology.

Operation 1510 gradually installs the solar panels produced by the solar panel plant in the land, wherein the installed solar panels reach the solar power plant output after a construction time longer than an otherwise full time construction of the solar power plant. In general, the solar power plant trades construction time for a desired power selling price or a desired capital investment.

Operation 1512 gradually replaces the previously installed solar panels with the newly produced solar panels after completing the installation of the solar panels for the solar power plant. In general, the replacement is performed when the performance of the previously installed solar panels is no longer satisfactory.

In an embodiment, some of the previously described operations are optional, meaning the present solar power plant might or might not incorporate all of these operations.

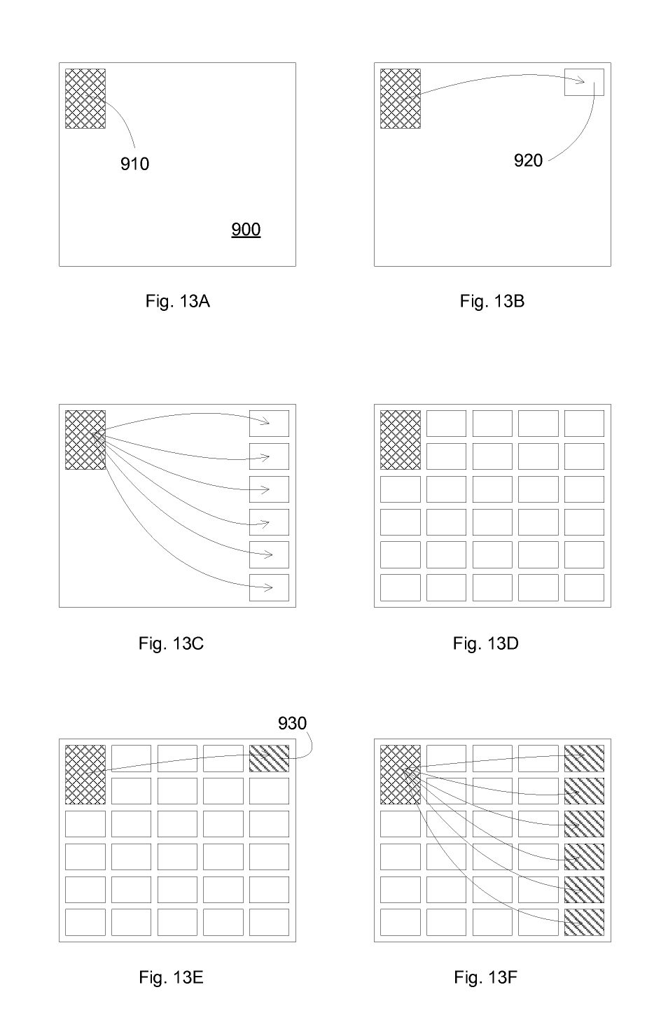

FIGS. 13A-13F illustrate an exemplary sequence of solar panel installation according to embodiments of the present invention. Land 900 is selected, and a solar panel plant 910 is constructed on the land 900 (FIG. 13A). Alternatively, the solar panel plant 910 can be constructed in a nearby location. The solar panel plant can be constructed at full time construction rate or gradually. The first solar panels 920 produced from the solar panel plant are installed on the land (FIG. 1B), together with subsequent solar panels (FIG. 13C) until reaching the desired power output, typically when the land is filled with solar panels (FIG. 13D). When the first solar panels 920 fail, for example, due to reaching life time, the next solar panels 930 produced from the solar panel plant can replace them (FIG. 13E). The replacement occurs continuously for all failed solar panels (FIG. 13F). If any individual solar panels fail prematurely, new solar panels can be used to perform replacement (not shown).

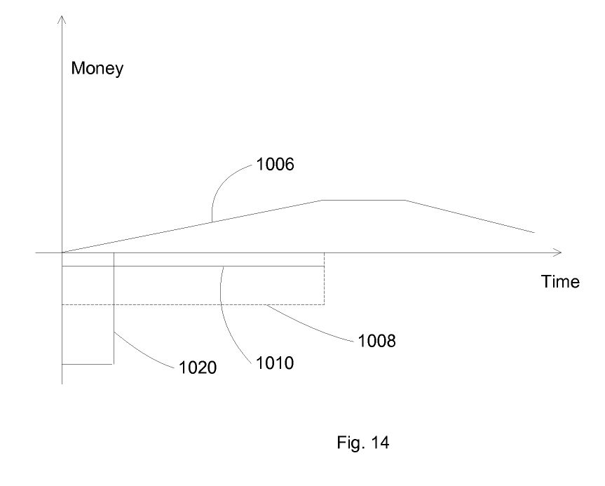

FIG. 14 illustrates a comparison between solar power plant with and without a solar panel plant. The revenue 1006 is about the same, since the solar panel plant is designed to produce solar panels at a same rate as the purchased ones. The difference is in the capital spending on the solar panels. For solar power plant without solar panel plant, the cost of solar panels 1008 is constant throughout the construction phase, assuming there is no cost reduction in solar technology. For solar power plant with a solar panel plant, there are the cost 1020 of constructing the solar panel plant, and the cost 1010 of materials and labor to produce the solar panels. After constructing the solar panel plant, the cost 1010 of the produced solar panels is lower as compared to the purchased cost 1008 of solar panels. This provides a long term cost reduction for the solar power plant, offset by early capital spending in constructing the solar panel plant, and provides benefits in the long run.

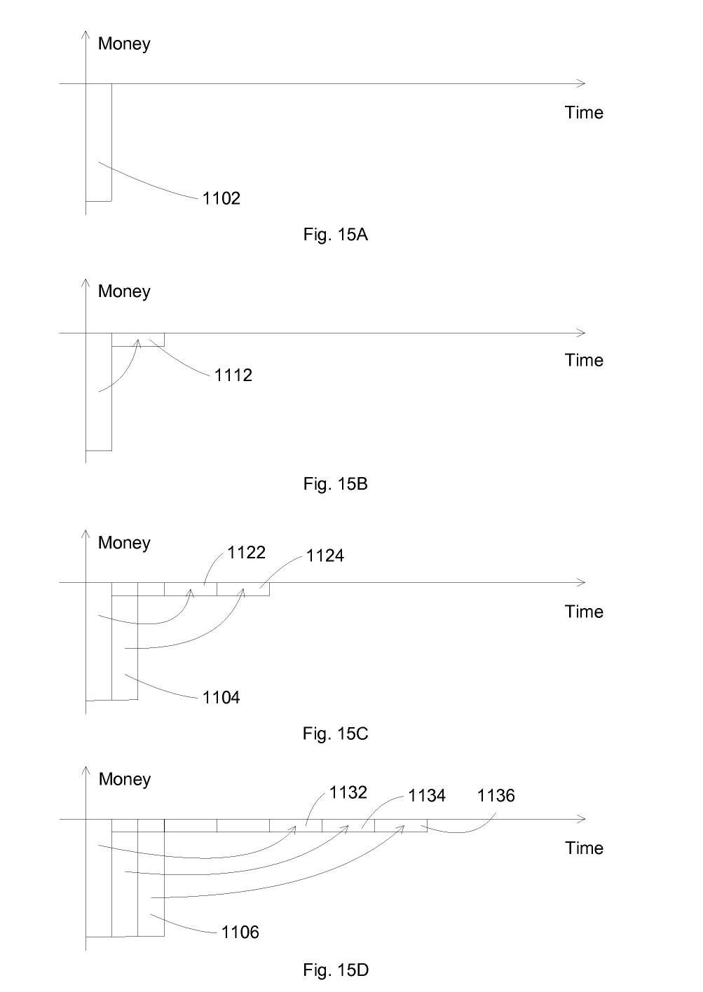

FIGS. 15A-15D illustrate a schematic construction of a solar panel plant in stages according to embodiments of the present invention. A first stage 1102 of solar panel plant is constructed, preferably with complete facilities for producing solar panels (FIG. 15A). The first staged solar panel plant starts produces solar panels 1112, which are installed in the solar power plant (FIG. 15B). In the same time, the second stage 1104 of solar panel plant is constructed, and the solar panels 1122 and 1124 from the first and second stages, respectively, of the solar panel plant are installed (FIG. 15C). Subsequent stage 1106 of the solar panel plant is constructed, and the produced solar panels 112, 1134, and 1136 from the stages of the solar panel plant are installed (FIG. 15D).

In an embodiment, the present invention provides a schematic algorithm for designing a solar power plant to achieve a desired criterion, such as a cost for the generated electricity comparable to the existing energy technologies or a desired capital investment for the construction of a solar power plant, taking into account the existing solar technology as well as potential future developments.

Comparable electricity cost is recognized as a main factor in designing a solar power plant. Since solar technology is an emergent technology, under normal conditions, solar power plants would require a premium price for the electricity they produce. However, an energy price premium significantly hinders the deployment of solar power plant, requiring substantial subsidization. Additionally, initial capital spending or investment is also an important factor, for example, to reduce the subsidization. Thus these two factors represent a focus for the present methodology or simulation of a design for a solar power plant, and other design variables are considered based on at least one of these factors, such as construction time, solar technology and cost reduction plans.

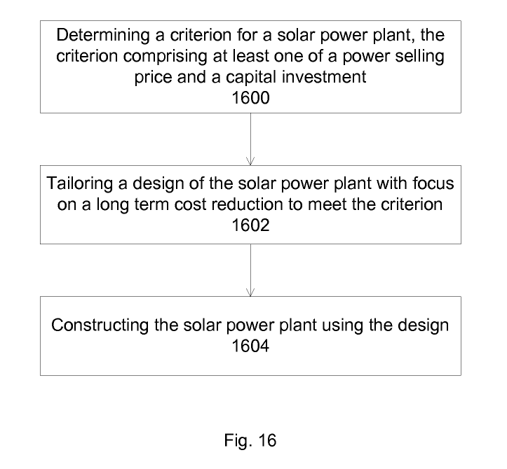

FIG. 16 illustrates an exemplary flowchart of a solar power plant according to embodiments of the present invention. Operation 1600 determines a criterion for the solar power plant with the criterion comprising at least one of a power selling price and a capital investment. In an embodiment, the power selling price is a first criterion and the capital investment is a second criterion, considered after satisfying the first criterion. In this case, the selling price is a main consideration, with the capital investment changeable within a small range of values. In an embodiment, the capital investment is a first criterion and the power selling price is a second criterion, considered after satisfying the first criterion. In this case, the capital investment is a main consideration, with the power selling price changeable within a small range of values, for example, the power selling price is required to be comparable, e.g., not higher than 10% of the existing technology price, and not required to be the same or less. In an embodiment, both capital investment and power selling price are considered equal, with the solar power plant satisfying both criteria. Operation 1602 tailors a design of the solar power plant with focus on a long term cost reduction to meet the criterion. The designs of the solar power plant can include selecting a base solar technology, considering potential improvements on the base solar technology, constructing in-house solar panel plant, and calculating a rate of construction for the solar power plant and/or the solar panel plant. Optional operation 1604 constructs the solar power plant using the design.

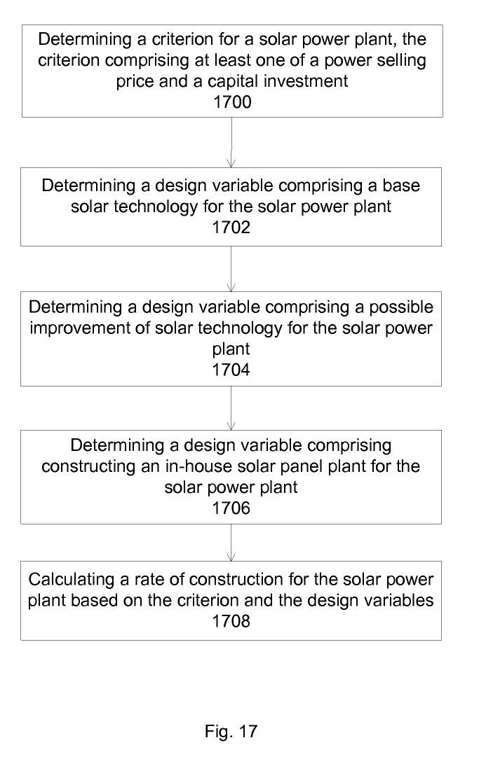

FIG. 17 illustrates an exemplary flowchart of a solar power plant according to embodiments of the present invention. Operation 1700 determines a criterion for the solar power plant with the criterion comprising at least one of a power selling price and a capital investment. Operation 1702 determines a design variable comprising a base solar technology for the solar power plant. Operation 1704 determines a design variable comprising a possible improvement of solar technology for the solar power plant. Operation 1706 determines a design variable comprising an in-house solar panel plant for the solar power plant. Operation 1708 calculates a rate of construction for the solar power plant based on the criterion and the design variables

Long term reliability is recognized as a main factor in the power that can be generated from the solar plant. Thus in an aspect, equipment lifetime is a main consideration in designing and building a solar power plant. The main equipment in a solar power plant is solar panels, thus in aspect, the present invention discloses a solar power plant with the highest proven lifetime for its solar panels, for example, to achieve a desired criterion, such as lowest cost of electricity and/or lowest capital spending.

The present invention discloses that, for a solar power plant, the proven long term reliability of the solar panels is one of the important features in the design and selection of solar power equipment. The reliability characteristic can be much more important than other characteristics of a solar power plant, such as lower cost solar panels or higher efficiency solar panels. For example, low cost, low reliability solar panel will require the additional cost of replacement, such as gradual degradation, sale overhead, transportation, installation and disposal. Thus for a same factor, low cost and low reliability solar panels provide less power in their lifetime than high cost, high reliability solar panels. The present invention further provides a simulator to calculate the exact point of tradeoff between cost and reliability, based on factors such as cost value, reliability value, gradual degradation value, sale overhead, transportation, installation and disposal.

Thus the present invention discloses a solar power plant that focuses on long term reliability, with solar panel cost being a secondary consideration. For example, if long term reliability of a solar panel is not well proven, or proven to be less than optimum, then the low cost of that solar panel should not be considered when establishing a solar power plant. With large number of solar panels to be installed in a solar power plant, statistical process, calculated based on large data, of mean and deviation values is used to determine the properties of solar panels from a certain technology or a fabrication plant.

Thus the present invention discloses a solar power plant that focuses on long term reliability, with high efficiency being a secondary consideration. For example, for new technology with high efficiency solar panels, reliability is not well proven since there is not yet any data on the long-term behavior of the new technology panels, even though the initial data indicates an improved efficiency.

In an embodiment, the present invention recognizes that solar power is an emergent technology, and thus the cost of electricity generated from a solar panel is strongly dependent on its established life time. For example, newly developed technology might provide higher solar conversion efficiency, but as with any new technology, long term reliability is not established, and it is reasonable to assume shorter panel life time with reduced efficiency with exposure time. Thus a same factor, high efficiency, unproven reliability solar panels can provide less power in their lifetime than low efficiency, proven reliability solar panels. The present invention further provides a simulator to calculate an estimated point of tradeoff between efficiency and reliability, based on factors such as energy conversion efficiency, estimated reliability, degradation rate, production and overhead costs, transportation, installation and financing costs. The simulator also provides estimate for the reliability and possible long term degradation of the high efficiency, new technology solar panels, based on the available data together with projected data of the new panels. Also trends and maturity of other similar new technologies are also taken into account in providing estimate for the long term reliability.

In an embodiment, the present invention employs the improvement of the emergent technology to increase the power generation of a solar power plant. For example, in solar technology, the learning curve is swift, and within a few years, technology improvement can be clearly noticeable. Thus the present invention discloses a gradual built-up of solar panels in a solar power plant, to take advantages of the rapid technology improvement, such as improvements in efficiency, fabrication processes and equipment manufacturing for better efficiency, better cost reduction or better reliability. In an aspect, the present solar power plant is built gradually, for example, sections by sections with adequate time between section for implementing technology improvement. For example, a first section of the solar power plant is built with a first generation of solar panels. One to two years later (or more or less, depending on the pace of technology advancement), a second section of the solar power plant is built with a second generation of solar panels. The plant is then built gradually until the technology is considered to be mature. This plan satisfies the immediate need of power generation, together with the advantage of higher power generation due to better solar panels. Alternatively, a portion or all of the installed solar panels can be upgraded or replaced with new technology panels, depending on the consideration of cost-effectiveness.

The gradual implementation of solar panels can also be based on power needs. Enough solar panels using current technology can be installed to satisfy the current power needs, for example, to supplement other forms of power generators or to bring power to a new location. When the needs increase, additional solar panels can be installed to address the new demands. The additional solar panels thus can employ new solar technology, since the time delay should be adequate for the introduction of newer solar generation. After the technology is mature, the solar power plant can grow with the mature solar panels. This gradual solar power implementation can bring high solar power generation, and at the same time, addressing the present needs for power.

In an embodiment, the present invention discloses a simulator for the design of a solar power plant to achieve one or more desired criteria. Among the factors being considered in the simulator, reliability is found to be a main factor in the amount of generated power. For example, solar technologies with 30+ years of development (such as single crystal silicon solar cell) can provide data on the long term performance of the solar panels, the modes of failures or degradation conditions, the environment conditions that can affect the power generation, and the effects of ambient temperature or sunlight angles. With these lifetime data, simulation can be performed to provide reliable projections of the amount of power which can be generated for the solar panels at any specific location and the installation requirements.

For newer solar technology with less data on long term reliability, the present simulator provides projections and estimates based on available data, and on the progress of similar technologies. In addition, reliability data can be projected from available data and accelerated experiments, together with early failure data from similar emergent technology. In general, the present simulator found that reliability of emergent technologies such as CIGS solar cells, polymer solar cells or flexible solar cells is less than desirable, which leads to lower power generation for a solar power plant. Without special consideration, implementing new solar technology, in general, would not provide the best power generation.

To take advantage of the new solar technologies, the present simulator provides a gradual implementation scheme of new technology, taking into account the power needs, the projected advancement of new solar technology, and other factors, to achieve a maximum power generation for a solar power plant during its lifetime. The scheme can provide a continuous build out of solar panels, for example, to achieve improved cost effectiveness in a solar power plant. The plant capacity can gradually increase, adding new solar panels when the needs arise or when new generation of technology is available.

The present simulator also provides a key decision on the degradation of solar cells, for example, the possible power loss when running continuously under the solar power plant conditions during its lifetime, the solar panel technology, the ambient conditions such as temperature, humidity, wind factor, dust and debris, sunlight amount and angles, and other factors. Proven reliability solar technology can provide degradation information on the solar panels, and the power site can provide ambient data. For new solar technology, the present simulator can provide estimate and projection based on available data.

The present simulator also provides other information consideration to achieve a maximum profit for a solar power plant, for example, the amount of oil and natural gas that can be saved versus a standard power plant. For example, the present simulator can consider the advantage due to the discount price for oil for an oil power plant, and use this information to achieve a realistic cost per solar generated power.

The present simulator also consider other components of solar panels, such as the inverters, the power transmission, and the power storage (e.g., battery) for their characteristics such as improvement, efficiency, degradation and long term reliability.

In an embodiment, the present simulator provides a selection of solar panel technologies, for example, between single crystal silicon solar cells, amorphous or poly silicon solar cells, CdTe solar cells, CIGS solar cells, organic solar cells, and a selection between substrate technologies such as silicon substrates, glass substrates, rigid substrates or flexible substrates. A basic criterion for the selection is the amount of generated power during the lifetime of the installed solar panels. In general, the simulator discloses that the main factors to be considered include the reliability of the solar panels, and the environment conditions where the solar panels will be installed. The cost and efficiency of the solar panels remain a second consideration, especially for solar panel with unknown long term reliability. The simulator can provide the exact point of tradeoff between reliability, cost, efficiency and other factors, based on available and projected data for existing and emergent solar technologies. In an aspect, the location of the solar power plant is first selected, and the simulator can calculate the solar technology to achieve the best power generation based on the conditions of the plant site, the availability of the existing solar technologies and the maturity of the emergent solar technologies. In general, the simulator found that mature solar technology has the best chance of success, easily surpassing low cost and emergent high efficiency solar technologies. In an aspect, the simulator can survey the possible power locations and provide suggestions for the most suitable sites and technologies.

The simulator can also evaluate a scheme of gradual build up of a solar power plant, balancing the maturity of some early solar technologies with the promising high efficiency and ease of fabrication of emergent solar technologies. The gradual built up scheme of a solar power plant can provide high return of power generation. In addition, the simulator can take into account other factors related to power generation to further optimize the return of investment in a solar power plant. For example, the simulator can suggest taking the incentive for green energy production, or for oil discount value in comparing with oil power plant to achieve a lower cost of power.

While the invention has been described and illustrated in connection with the preferred embodiments of solar power plants, many variations and modifications, as will be apparent to those of skill in the art, may be made without departing from the spirit and scope of the invention, such as applications to other emergent technologies. The invention as set forth in the appended clams is thus not limited to the precise details of construction set forth above as such variations and modifications are intended to be included within the spirit and scope of the invention as set forth in the defined claims.

What is claimed is:

1. A method for constructing a solar power plant, comprising:
securing land for a solar power plant output;
gradually installing solar panels to reach the solar power plant output after a construction time longer than an otherwise full time construction of the solar power plant.

2. A method as in claim 1 wherein the construction time is between 2 and 30 times longer than an otherwise full time construction of the solar power plant.

3. A method as in claim 1 wherein the construction time is between ten and 30 years.

4. A method as in claim 1 wherein the construction time is selected to achieve a desired capital spending or a desired power selling price.

5. A method as in claim 1 further comprising
installing subsequent solar panels with improved solar technology as compared to previous solar panels.

6. A method as in claim 1 further comprising
gradually replacing solar panels that have reached their life time.

7. A method as in claim 1 wherein the solar power plant grows without any additional capital spending.

8. A method for constructing a solar power plant, comprising:
securing a land for a solar power plant output;
constructing a solar panel plant for producing solar panels in the land or in a vicinity of the land, wherein the solar panel production rate of the solar panel plant is a fraction of the solar power plant output;
gradually installing the solar panels produced by the solar panel plant in the land, wherein the installed solar panels reach the solar power plant output after a construction time longer than an otherwise full time construction of the solar power plant.

9. A method as in claim 8 wherein the solar panel plant produces at least one of solar cells, solar panels assembly and solar plant accessories.

10. A method as in claim 8 further comprising
constructing the solar panel plant either at a full time construction rate or in stages with each stage producing solar panels at a portion of the solar panel plant production rate.

11. A method as in claim 8 further comprising
gradually replacing the previously installed solar panels with the newly produced solar panels after completing the installation of the solar panels for the solar power plant.

12. A method as in claim 8 further comprising
specially optimizing the solar panel plant for producing specific solar panels for the solar power plant with minimum variations in solar panel designs or features.

13. A method as in claim 8 wherein the production rate of the solar panel plant meets the solar power plant output after between 10 and 30 years.

14. A method as in claim 8 further comprising
incorporating improvements of solar technologies to the solar panel plant to produce improved solar panels.

15. A solar power plant having a solar power plant output, comprising:
a land;
a solar panel plant for producing solar panels in the land or in a vicinity of the land, wherein the solar panel production rate of the solar panel plant is a fraction of the solar power plant output;
a plurality of solar panels in the land for producing the solar power plant output, wherein the solar panels are gradually installed after being produced from the solar panel plant.

16. A solar power plant as in claim 15 wherein the solar panel plant produces at least one of solar cells, solar panels assembly and solar plant accessories.

17. A solar power plant as in claim 15 wherein the produced solar panels further gradually replace the installed solar panels after completing producing solar panels for the solar power plant.

18. A solar power plant as in claim 15 wherein the solar panel plant is specially optimized for producing specific solar panels of the solar power plant with minimum variations in solar panel designs or features.

19. A solar power plant as in claim 15 wherein the production rate of the solar panel plant meets the solar power plant output after between 10 and 30 years.

20. A solar power plant as in claim 15 wherein the solar panel plant incorporates incremental technology improvements.
